(19) United States
(12) Patent Application Publication
(10) Pub. No.: US 2007/0036022 A1
(43) Pub. Date: Feb. 15, 2007

(54) Synchronizer for multi-rate input data using unified first-in-first-out memory and method thereof

(75) Inventor: Suk-Beom Song, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 11/502,036

(22) Filed: Aug. 10, 2006

(30) Foreign Application Priority Data
Aug. 11, 2005 (KR) 10-2005-0073730

(51) Int. Cl. G11C 8/00

(52) U.S. Cl. 365/233

(57) ABSTRACT

In a synchronizer for multi-rate input data, a unified FIFO (first-in-first-out) memory receives multi-rate input data, converts the multi-rate input data into a single system operation frequency, and outputs converted data of a plurality of channels of the multi-rate input data, based on the control of a controller.

### CROSS-REFERENCE TO RELATED PATENT APPLICATION

This application claims the benefit of Korean Patent Application No. 10-2005-0073730, filed on Aug. 11, 2005, in the Korean Intellectual Property Office, the disclosure of which is incorporated herein by reference in its entirety.

### BACKGROUND OF THE INVENTION

1. Field of the Invention

The present invention relates to a data processing system, and more particularly to an apparatus and method for synchronizing multi-rate input data.

2. Description of Related Art

FIG. 1 is a block diagram of a data processing system 100 for processing multi-rate input data. Referring to FIG. 1, the data processing system 100 includes a memory 140 such as double data rate (DDR) SDRAM, buffers 110 to 130 such as dual port SRAM (DPSRAM), which buffer data D1 to D3 having different data rates, an interlace progressive converter (IPC) 150 for accessing the memory 140 through a bus, a scaler 160, and a data compressor 170 based on an MPEG protocol.

The data processing system 100 may be used for concurrently processing a HDTV broadcast signal and a conventional analog broadcast signal or a computer display signal to allow viewing of two signals through a single display apparatus. The IPC 150, the scaler 160, and the data compressor 170 read several frames or lines of data from the memory 140 to perform frequency converting, scaling, and compressing for processing corresponding signals. An internal buffer may be used for temporarily storing data read from the memory 140. To write or read data from/to the memory 140, a separate buffer is used for each channel.

In particular, the buffers 110 to 130 may be used so that input video data D1 to D3 having different data rates and synchronized with different clock signals CK1 to CK3 can be temporarily stored and be output at a predetermined data rate in synchronization with an output clock signal CK0. The buffers 110 to 130 buffer the video input data D1 to D3 and transfer the video input data D1-D3 into the memory 140 at a common data rate in synchronization with the output clock signal CK0. The output clock signal CK0 is an operation clock signal of the memory 140 and processors coupled to the bus.

As shown in FIG. 2, to perform input-output buffering at different frequencies, the DPSRAM processes a piece of data to perform a frequency conversion. As silicon-on chip (SOC) architecture has become prevalent in semiconductor integrated circuits, the scale and composition ratio of memories incorporated therein have increased, having a significant effect on the overall chip size. Therefore, effective memory management is increasingly needed. However, DPSRAM is physically twice as large as single port SRAM (SPSRAM), and systems using multiple DPSRAMs (for example, three DPSRAMs in the data processing system 100) for respective input data buffering cause a significant increase in the overall circuit size.

### SUMMARY OF THE INVENTION

According to an embodiment of the present invention, a synchronizer for multi-rate input data, comprises a memory, and a controller controlling an input and output of the memory, wherein the controller controls the memory to receive the multi-rate input data and to output output data corresponding to the multi-rate input data on a plurality of corresponding channels, the output having a single predetermined rate.

According to another embodiment of the present invention, a synchronizer for multi-rate input data, comprises a memory, an input control unit receiving at least two channels of input data having different frequencies and writing the input data in the memory, wherein the input data are converted to have a single predetermined operation frequency, and an output control unit transferring the input data written in the memory at the predetermined operation frequency based on bus arbitration.

The input control unit may comprise sampling frequency converters which respectively receive the input data, convert the input data into the predetermined operation frequency, and output the input data, and an input selector which outputs a selected channel of the input data to the memory by allocating time sections with respect to different channels of the input data, wherein the time sections are output from respective sampling frequency converters in proportion to the different frequencies of input data input through the channels.

The output control unit may comprise an output selector selecting channel outputs of the input data of the channels written in allocation addresses of the memory based on overflow and underflow conditions on an output path, and at least two control buffers temporarily storing respective channel output data which are output through the memory and the output selector, and outputting the temporarily stored channel output data at the predetermined operation frequency based on the bus arbitration of a bus arbiter.

According to another embodiment of the present invention, a method of synchronizing multi-rate input data comprises receiving the multi-rate input data from at least two channels, converting the multi-rate input data into a single predetermined operation frequency, writing converted channel data corresponding to the multi-rate input data to a single memory, and outputting the converted channel data written to the memory at the predetermined operation frequency based on bus arbitration.

### BRIEF DESCRIPTION OF THE DRAWINGS

The present invention will become more apparent by describing in detail exemplary embodiments thereof with reference to the attached drawings in which:

FIG. 1 is a block diagram of a general data processing system for processing multi-rate input data;

FIG. 2 is a view of a general DPSRAM for processing multi-rate input data;

FIG. 3 is a conceptual view of a synchronizer for multi-rate input data according to an embodiment of the present invention;

FIG. 4 is a detailed block diagram of a synchronizer according to an embodiment of the present invention;

FIG. 5 is another detailed block diagram of a synchronizer according to an embodiment of the present invention;

FIG. 6 is a detailed block diagram of sampling frequency converters of FIG. 5;

FIG. 7 is a diagram showing the operation of flow control buffers of FIG. 5;

FIG. 8 is a detailed block diagram of flow control buffers of FIG. 5; and

FIG. 9 is a flowchart of the operation of an output selector according to an embodiment of the present invention.

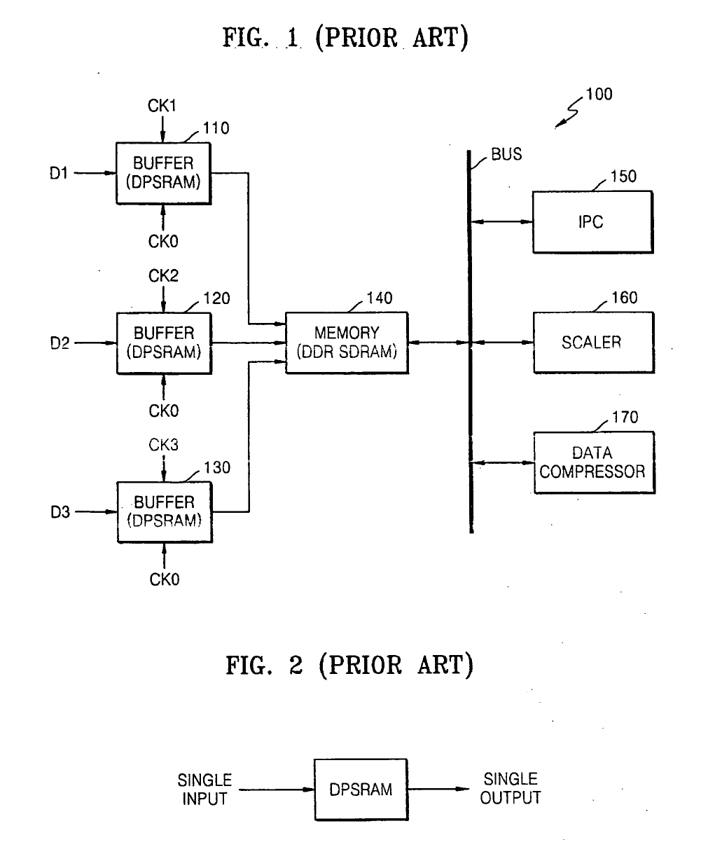

### DETAILED DESCRIPTION OF PREFERRED EMBODIMENTS

The present invention will now be described in detail by explaining exemplary embodiments of the invention with reference to the attached drawings. Like reference numerals denote like elements in the drawings.

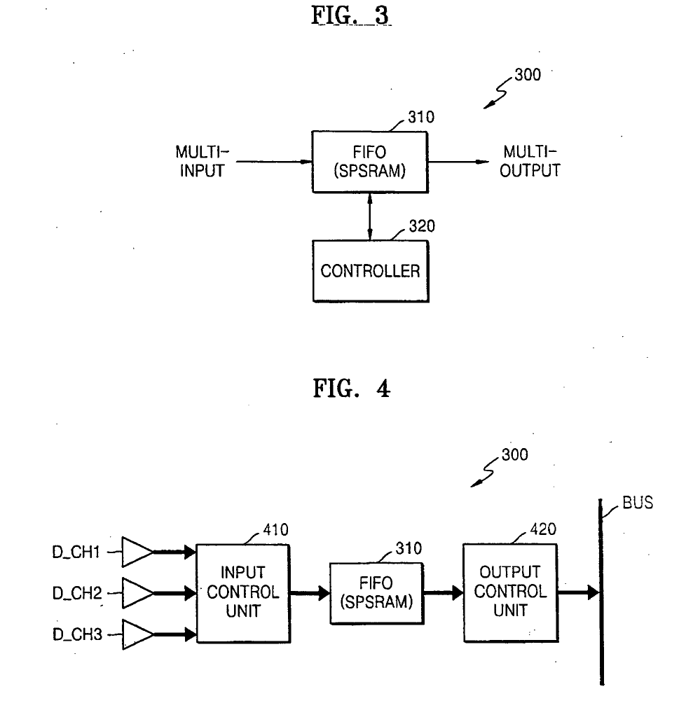

FIG. 3 is a conceptual view of a synchronizer 300 for multi-rate input data according to an embodiment of the present invention. Referring to FIG. 3, the synchronizer 300 includes a memory 310, e.g., SPSRAM, and a controller 320 controlling the input and output of the memory 310.

The synchronizer 300 concurrently processes asynchronous multi-rate signals, such as a HDTV broadcast and a conventional analog broadcast or a computer display signal, to be transferred to a single display apparatus, to display two or more signals at the same time. When only one unified first-in-first-out (FIFO) type SPSRAM is used, the memory 310 can receive multi-rate input data and output a plurality of corresponding channels of data that have been converted into a system operation rate or frequency according to the controller 320. Thus, overall chip size can be reduced. The terms rate and frequency are used interchangeably throughout the disclosure.

FIG. 4 is a detailed view of the synchronizer 300 of FIG. 3 according to an embodiment of the present invention. Referring to FIG. 4, the synchronizer 300 includes the memory 310, an input control unit 410, and an output control unit 420. The input control unit 410 and the output control unit 420 correspond to the controller 320 of FIG. 3.

The input control unit 410 controls the memory 310 such that the memory 310 can receive multi-rate input data through a plurality of channels of data D_CH1 to D_CH3 and store a plurality of corresponding channels of data that have been converted into the system operation frequency. The output control unit 420 is arbitrated for bus occupation and controls the memory 310 such that the data written in the memory 310 can be output to a bus at the system operation frequency. Three multi-rate input data channels are shown in the drawing, but at least two channels having asynchronous data may be used according to a system specification.

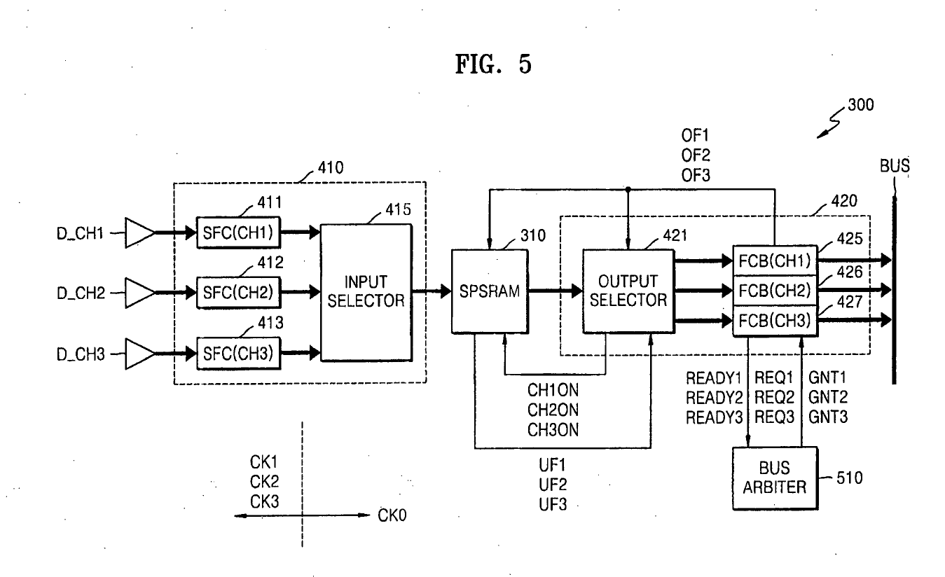

FIG. 5 is a detailed view of the synchronizer 300 of FIG. 4 according to an embodiment of the present invention. Referring to FIG. 5, the input control unit 410 of FIG. 4 includes a plurality of sampling frequency converters 411 to 413 and an input selector 415. The output control unit 420 of FIG. 4 includes an output selector 421 and a plurality of flow control buffers 425 to 427. A bus arbiter 510 may be further included to arbitrate the bus occupation of the plurality of flow control buffers 425 to 427.

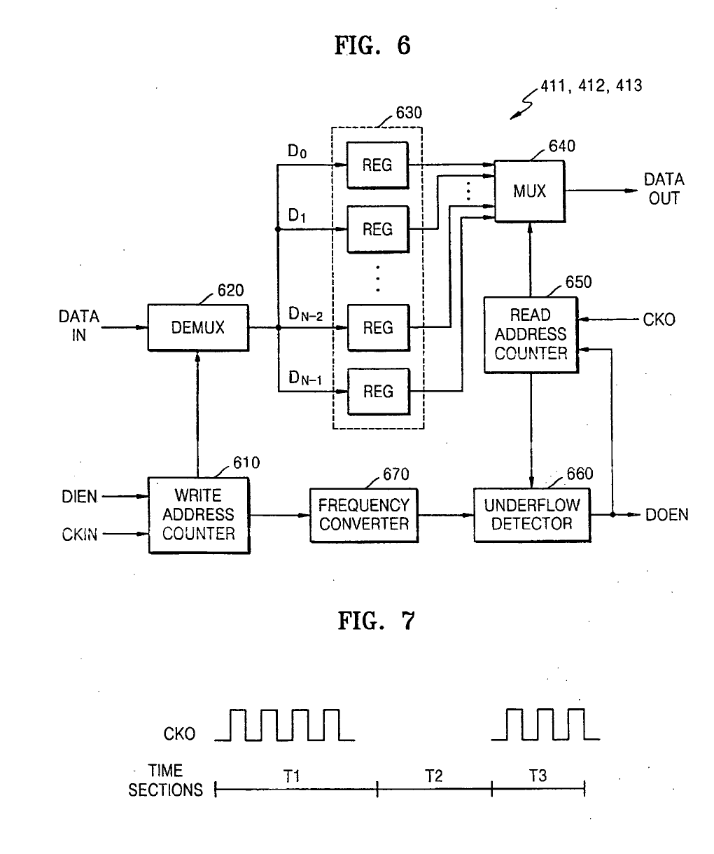

The plurality of sampling frequency converters 411 to 413 receive respective input data of multi-rate channels D-CH1, D-CH2, and D_CH3, and output the data after converting the data into the output clock signal CK0 frequency, that is, the system operation frequency. The multi-rate channel input data is received by the input control unit 410 being respectively synchronized with input clock signals CK1, CK2, and CK3. The multi-rate channel input data is synchronized with the output clock signal CK0 by the plurality of sampling frequency converters 411 to 413. The plurality of sampling frequency converters 411 to 413 will now be described in detail with reference to FIG. 6.

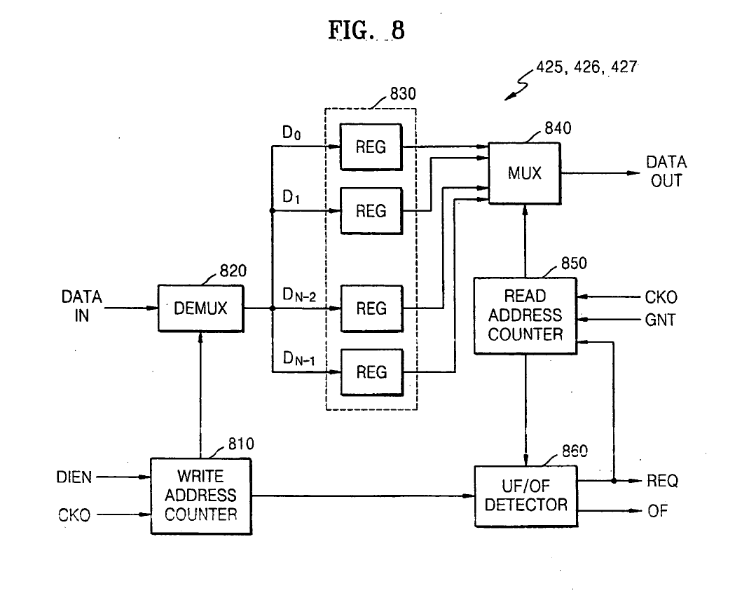

With respect to data of each channel that is output from each of sampling frequency converters 411 to 413, the input selector 415 allocates time sections in proportion to the rate of each input data input through each of the channels D_CH1, D_CH2, and D_CH3, and outputs the data of each channel to the memory 310. For example, if the data rates of the first channel D-CH1, the second channel D-CH2, and the third channel D_CH3 are in decreasing order (i.e., the first channel D-CH1 has the highest data rate), then as shown in FIG. 7, time sections are allocated in the first channel D-CH1, the second channel D-CH2, and the third channel D_CH3 such that T1>T2>T3. According to the time sections, the input selector 415 outputs the corresponding channel data to the memory 310. This allows more data to be output in synchronization with the same output clock signal CK0 by increasing allocated times when the data rate is high. Thus, concurrent display of all multi-rate input data can be carried out simultaneously in a display apparatus. As in the case of a round robin scheduling manner, the input selector 415 outputs the channel data to the memory 310 with the top priority for each of the allocated time sections (T1>T2>T3).

The memory 310 stores the channel data received from the input selector 415 in allocation address areas. When bus grant signals GNT1, GNT2, and GNT3 from the bus arbiter 510 are activated, a predetermined amount of channel data can be transferred to the bus without substantial delay. The output selector 421 and the plurality of flow control buffers 425 to 427 for respective channels transfer data from the memory 310 to the bus. If the output selector 421 and the plurality of flow control buffers 425 to 427 are not provided, at least one clock cycle of latency may be needed when the bus is granted. Thus, a circuit according to an embodiment of the present invention has a structure that can improve data transfer throughput along with a reduced chip size.

Referring to FIG. 5, the output selector 421 selects channel outputs of the plurality of channels of data written in the allocation address areas of the memory 310 to be output. The output selector 421 controls data which is output from the memory 310 based on overflow and underflow conditions on an output path.

The plurality of flow control buffers 425 to 427 are arbitrated by the bus arbiter 510 when using buses. When an internal data flow is not in an underflow condition, the plurality of flow control buffers 425 to 427 request the bus by activating bus request signals REQ1, REQ2, and REQ3. In response to the bus request signals REQ1, REQ2, and REQ3, when the bus arbiter 510 activates the bus grant signals GNT1, GNT2, and GNT3, the flow control buffers 425 to 427 activate corresponding channel ready signals READY1, READY2, and READY3, and output the corresponding channel data received from the output selector 421 to the bus.

An overflow condition on the output path means that a data flow is in an overflow condition inside the plurality of flow control buffers 425 to 427. To indicate an overflow condition, the plurality of flow control buffers 425 to 427 activate overflow signals OF1, OF2, and OF3 (for example, see FIG. 8). In addition, an underflow condition on the output path means that a data flow is in an underflow condition inside the memory 310. To indicate an underflow condition, the memory 310 activates underflow signals UF1, UF2, and UF3.

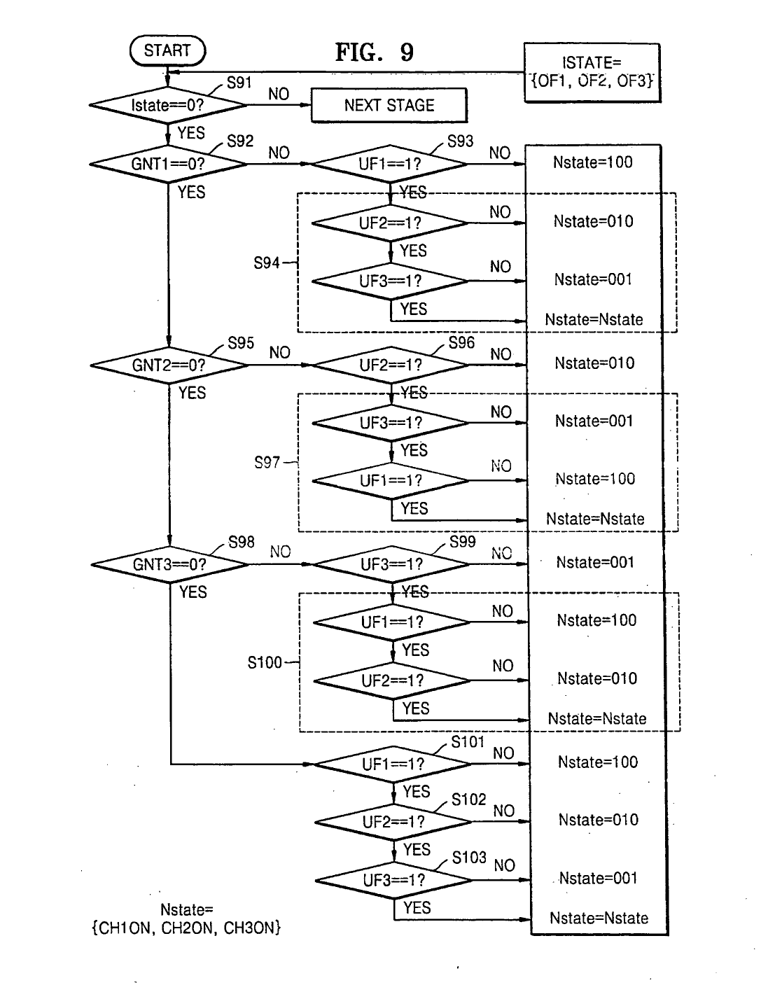

For example, if one of the plurality of flow control buffers 425 to 427 is not in an overflow condition (e.g., OF1, OF2, and OF3 are “0”), and storage areas allocated at each channel of the memory 310 are not in an underflow condition (e.g., UF1, UF2, and UF3 are “0”), the output selector 421 transfers corresponding channel open signals CH1ON, CH2ON, and CH3ON to the memory 310. Accordingly, when the corresponding channel data written in the memory 310 is output from the memory 310, the output selector 421 outputs the corresponding channel data to a flow control buffer which is not in an overflow condition. The operation of the output selector 421 will be described in detain with reference to FIG. 9.

Based on the bus arbitration of the bus arbiter 510, the plurality of flow control buffers 425 to 427 temporarily store respective channel outputs which are output through the memory 310 and the output selector 421, and output the temporarily stored channel data at the output clock signal CK0 frequency. The plurality of flow control buffers 425 to 427 will be described in detail with reference to FIG. 8.

FIG. 6 is a detailed block diagram of the sampling frequency converters 411 to 413 of FIG. 5. Referring to FIG. 6, the sampling frequency converters 411, 412, and 413 each include a write address counter 610, a demultiplexer 620, a register 630, a multiplexer 640, a read address counter 650, an underflow detector 660, and a frequency converter 670.

The write address counter 610 counts pulses of corresponding channel input clock signals CKIN to create a write address based on an enable signal DIEN, which is activated when input data of corresponding channels is received. The write address to be counted is reset whenever the enable signal DIEN is activated, and can be increased by one based on a pulse of the input clock signal CKIN.

The frequency converter 670 converts the write address, which is output from the write address counter 610, into the output clock signal CK0 frequency.

The demultiplexer 620 outputs corresponding channel input data DATAIN to the write address which is output from the write address counter 610. The register 630 stores the data in a register cell REG corresponding to the write address output from the write address counter 610. Since sum of the rates of all input data DATAIN which is input through the channels D-CH1, D-CH2, and D_CH3 needs to be less than the output clock signal CK0 frequency, the number of register cells REG is determined in proportion to the data rate of each input data DATAIN. The register 630 operates in a FIFO mode.

The underflow detector 660 monitors the underflow condition of the register 630 based on the read address which is output from the read address counter 650 and the write address which is converted from the frequency converter 670.

The underflow of the register 630 can be determined according to algorithm 1.

[algorithm 1]

```
if(W_addr > R_addr)
  if(W_addr − R_addr < DELTA)
    Underflow = 1
  else Underflow = 0
else
  if(N + W_addr − R_addr < DELTA)
    Underflow = 1
  else Underflow = 0
```

In algorithm 1, W_addr denotes the last write address, R_addr denotes the last read address, DELTA denotes a critical value that can be set by a user, and N denotes the number of register cells. Regardless of whether W_addr is greater or less than R_addr, an underflow condition of the register 630 means that the last write address which is written in the register 630 and the last read address which is read from the register 630 have a difference of less than a predetermined critical value DELTA.

When an output DOEN of the underflow detector 660 indicates that it is not in an underflow condition, the read address counter 650 counts the output clock signal CK0 pulses to create the read address. When the output DOEN of the underflow detector 660 indicates that it is in an underflow condition, the read address counter 650 maintains the previous address.

The multiplexer 640 outputs data DATAOUT corresponding to the read address from the register 630.

When the register 630 is not in an underflow condition, the sampling frequency converters 411 to 413 output data DATAOUT in which the channel input data DATAIN has been converted into the output clock signal CK0 frequency.

FIG. 8 is a detailed block diagram of the flow control buffers 425 to 427 of FIG. 5. Referring to FIG. 8, the flow control buffers 425, 426, and 427 each include a write address counter 810, a demultiplexer 820, a register 830, a multiplexer 840, a read address counter 850, and an underflow/overflow detector 860. The read address counter 850 receives the output color signal CK0, and the underflow/overflow detector 860 monitors all of the underflow and overflow conditions.

The write address counter 810 counts pulses of output clock signals CK0 to create a write address based on an enable signal DIEN, which is activated when input data of corresponding channels is received from the output selector 421. The write address to be counted is reset whenever the enable signal DIEN is activated, and can be increased by one based on the pulse of the input clock signal CKIN.

The demultiplexer 820 outputs corresponding channel input data DATAIN to the write address which is output from the write address counter 810. The register 830 stores the data in a register cell REG corresponding to the write address based on the write address output from the write address counter 810. The register 830 operates in a FIFO mode.

The underflow/overflow detector 860 monitors the underflow and overflow conditions of the register 830 based on the read address which is output from the read address counter 850 and the write address which is created by the write address counter 810. When the register 830 is not in an underflow condition, the underflow/overflow detector 860 activates the bus request signals REQ1, REQ2, and REQ3 to request the bus (e.g., REQ1, REQ2, and REQ3 are “1”). In addition, the underflow/overflow detector 860 feeds back the overflow signals OF1, OF2, and OF3 that show whether the register 830 is in the overflow condition to the output selector 421 and the memory 310.

The underflow of the register 830 can be determined according to algorithm 1, and the overflow of the register 830 can be determined according to algorithm 2.

[algorithm 2]

```
if(W_addr > R_addr)
  if(N + W_addr − R_addr < DELTA)
    Overflow = 1
  else Overflow = 0
else
  if(R_addr − W_addr < DELTA)
    Overflow = 1
  else Overflow = 0
```

In algorithm 2, W_addr denotes the last write address, R_addr denotes the last read address, DELTA denotes a critical value that can be set by a user, and N denotes the number of register cells. Regardless of whether W_addr is greater or less than R_addr, the underflow and overflow conditions of the register 830 mean that the last write address which is written in the register 830 and the last read address which is read from the register 830 have a difference of less than a predetermined critical value DELTA.

When outputs REQ1, REQ2, and REQ3 of the underflow/overflow detector 860 are not in an underflow condition (e.g., REQ1, REQ2, and REQ3 are “1”, the read address counter 850 counts the output clock signal CK0 pulses to create the read address. When outputs REQ1, REQ2, and REQ3 of the underflow/overflow detector 860 are in an underflow condition (e.g., REQ1, REQ2, and REQ3 are “0”), the read address counter 850 maintains the previous address. Accordingly, when the bus arbiter 510 activates the bus grant signals GNT1, GNT2, and GNT3 in response to the activated bus request signals REQ1, REQ2, and REQ3 of the underflow/overflow detector 860, the read address counter 850 outputs the created read address to the multiplexer 840, and the multiplexer 840 outputs data corresponding to the read address from the register 830 to the bus. When the multiplexer 840 outputs the data to the bus, the channel ready signals READY1, READY2, and READY3 may be activated to transfer the data to the bus arbiter 510.

When the outputs OF1, OF2, and OF3 of the underflow/overflow detector 860 are not in an overflow condition (e.g., OF1, OF2, and OF3 are “0”), and storage areas allocated at each channel of the memory 310 are not in an underflow condition (e.g., UF1, UF2, and UF3 are “0”), the output selector 421 transfers corresponding channel data from the memory 310 to the flow control buffers 425 to 427. When the register 830 is not in an underflow condition (e.g., REQ1, REQ2, and REQ3 are “1”), the flow control buffers 425, 426, and 427 output corresponding channel output data DATAIN from the output selector 421 to the flow control buffers 425, 426, and 427 which are not in an overflow condition, based on the bus grant signals received from the bus arbiter 510.

FIG. 9 is a flowchart of the operation of the output selector 421, taking an example of a 3-bit state function of ISTATE==0. ISTATE is a 3-bit logic state function of overflow signals OF1, OF2, and OF3, which are respectively created by the flow control buffers 425 to 427. Referring to FIG. 9, operation S91 begins with ISTATE==0 since the flow control buffers 425 to 427 have no data in an initial stage. In operation S92, if the bus is granted by the bus arbiter 510 with respect to the first channel (GNT1==1), and in operation S93, if the first channel area of the FIFO memory 310 is not in an underflow condition (UF1==0), the output selector 421 activates the first channel open signal CH1ON (Nstate=100), SO that data of the FIFO memory 310 in the first channel area can be stored in the first flow control buffer 425. The first flow control buffer 425 activates the first ready signal READY1 to transfer the data received from the FIFO memory 310 to the bus.

When there is no data to be transferred from the FIFO memory 310, the first channel area of the FIFO memory 310 changes to an underflow condition (UF1==1) in operation S93. In operation S94, to avoid an overall system hold condition, the same operation of operation S93 is performed with respect to the second and third channels. Thus, the output selector 421 activates the second open signal CH2ON or the third open signal CH3ON (Nstate=010/001), so that the first or second area data of the FIFO memory 310 can be stored in the second or third flow control buffer 426 or 427. When the first, second, and third channel areas of the FIFO memory 310 are all in an underflow condition, the previous state is held (Nstate=Nstate).

When the bus is granted with respect to any one of the flow control buffers 425 to 427, and the corresponding channel area of the memory 310 is in an underflow condition, the corresponding channel data written in the memory 310 is stored in a different flow control buffer based on the control of the output selector 421, so that the flow control buffer can immediately occupy the bus, e.g., within less than one clock cycle, when it attains the bus grant. As a result, a bus throughput decrease caused by lack of data on the flow control buffers 425 to 427 can be substantially avoided.

In operation S92, if the bus is not granted by the bus arbiter 510 with respect to the first channel (GNT1==0), and the bus is granted with respect to the second or third channel (GNT2/GNT3==1), operations S95 to S100 proceed similarly to operations S92 to S94.

If the bus occupation is not granted in operations S92, S95, and S98 (GNT1==0, GNT2==0, and GNT3==0), and the first channel area of the FIFO memory 310 is not in an underflow condition (UF1==0) in operation S101, the output selector 421 activates the first channel open signal CH1ON (Nstate=100), so that the data of the FIFO memory 310 in the first channel area can be stored in the first flow control buffer 425. The first flow control buffer 425 activates the first ready signal READY1 to transfer the data received from the FIFO memory 310 to the bus.

When there is no more data to be transferred from the FIFO memory 310, the first channel area of the FIFO memory 310 changes to an underflow condition (UF1==1) in operation S101. In operations S102 and S103, to avoid an overall system hold condition, the same operation of operation S101 is performed with respect to the second and third channels. Thus, the output selector 421 activates the second open signal CH2ON or the third open signal CH3ON (Nstate=010/001), so that the first or second area data of the FIFO memory 310 can be stored in the second of third flow control buffer 426 and 427. When the first, second, and third channel areas of the FIFO memory 310 are all in an underflow condition, the previous state is held (Nstate=Nstate).

Even though one of the flow control buffers 425 to 427 does not attain the bus grant, the corresponding channel data written in the memory 310 is stored in a different flow control buffer based on the control of the output selector 421, so that the flow control buffer can immediately occupy, e.g., within less than one clock cycle, the bus when it attains the bus grant. As a result, a bus throughput decrease caused by lack of data on the flow control buffers 425 to 427 can be substantially avoided.

Even when ISTATE==0 state is not satisfied in operation S91, the operation S91 proceeds similarly to the operations S92 to S103. Thus, when the FIFO memory 310 is in an underflow condition, regardless of whether the flow control buffers 425 to 427 attain the bus grant, the data is filled in advance in preparation for transfer when the bus is granted. In this case, more than one of the flow control buffers 425 to 427 are in an overflow condition. Thus, based on the control of the output selector 421, corresponding channel data from the memory 310 is stored in the flow control buffers 425, 426, and 427 which are not in an overflow condition.

In the synchronizer 300 according to an embodiment of the present invention, the memory 310 receives multi-rate input data based on the control of the controller 320 to output data of a plurality of corresponding channels, which have been converted into one system operation frequency.

In a synchronizer for multi-rate input data according to an embodiment of the present invention, a plurality of asynchronous input signals are converted into a system operation frequency using one SPSRAM. The overall SOC chip size can be reduced as compared to a system having one DPSRAM per channel. Further, the synchronizer can improve the bus throughput, since output data which has been converted into the system operation frequency is stored in flow control buffers in advance when a unified FIFO memory is in an underflow condition, or before bus occupation is granted.

While the present invention has been particularly shown and described with reference to exemplary embodiments thereof, it will be understood by those skilled in the art that various changes in form and detail may be made therein without departing from the spirit and scope of the present invention.

What is claimed is:

1. A synchronizer for multi-rate input data, comprising:
a memory; and
a controller controlling an input and output of the memory wherein the controller controls the memory to receive the multi-rate input data and to output output data corresponding to the multi-rate input data on a plurality of corresponding channels, the output data having a single predetermined rate.

2. The synchronizer of claim 1, wherein the memory is a single port static random access memory.

3. The synchronizer of claim 1, wherein the memory is a first-in-first-out type.

4. A synchronizer for multi-rate input data, comprising:
a memory;
an input control unit receiving at least two channels of input data having different frequencies and writing the input data in the memory, wherein the input data are converted to have a single predetermined operation frequency; and
an output control unit transferring the input data written in the memory at the predetermined operation frequency based on bus arbitration.

5. The synchronizer of claim 5, wherein the input control unit comprises:
sampling frequency converters which respectively receive the input data, convert the input data into the predetermined operation frequency, and output the input data; and
an input selector which outputs a selected channel of the input data to the memory by allocating time sections with respect to different channels of the input data, wherein the time sections are output from the sampling frequency converters in proportion to the different frequencies of input data input through the channels.

6. The synchronizer of claim 5, wherein the sampling frequency converters output the input data which is converted into the predetermined operation frequency when an internal register of the sampling frequency converters is not in an underflow condition.

7. The synchronizer of claim 6, wherein the internal register is a first-in-first-out type, and the underflow condition of the internal register corresponds to an address difference between a last write address which is written in the internal register and a last read address which is read from the internal register that is less than a predetermined value.

8. The synchronizer of claim 5, wherein the input selector outputs the selected channel of the input data to the memory with a top priority once for each of the allocated time sections.

9. The synchronizer of claim 4, wherein the output control unit comprises:
an output selector selecting channel outputs of the input data of the channels written in the memory based on overflow and underflow conditions on an output path; and
at least two flow control buffers temporarily storing respective channel output data which are output through the memory and the output selector, and outputting the temporarily stored channel output data at the predetermined operation frequency based on the bus arbitration of a bus arbiter.

10. The synchronizer of claim 9, wherein the output selector outputs the channel output data corresponding to the input data written in the memory to the flow control buffers which are not in an overflow condition, when any one of the flow control buffers is not in an overflow condition and a corresponding channel area of the memory is not in an underflow condition.

11. The synchronizer of claim 9, wherein the flow control buffers output the channel data to a bus, when an internal register of the flow control buffers is not in an underflow condition and bus occupation is granted in response to a bus request.

12. The synchronizer of claim 11, wherein the internal register is a first-in-first-out type, and the underflow condition and an overflow condition of the internal register are determined by an address difference between a last write address which is written in the internal register and a last read address which is read from the internal register.

13. The synchronizer of claim 11, wherein when the bus occupation is granted with respect to any one of the flow control buffers, and a channel area of the memory is in an underflow condition, the input data written in the memory is stored in a different flow control buffer based on a selection of the output selector, wherein the different flow control buffer immediately occupies the bus when the different flow control buffer attains a bus grant.

14. The synchronizer of claim 11, wherein one of the flow control buffers do not attain a bus grant, the input data written in the memory is stored in a different flow control buffer based on a selection of the output selector, wherein the different flow control buffer immediately occupies the bus when the different flow control buffer attains a bus grant.

15. The synchronizer of claim 5, wherein each of the sampling frequency converters comprises:
a first counter counting pulses of a channel input clock signal corresponding to a channel of the input data to create a write address;
a frequency converter converting the write address into the predetermined operation frequency;
a demultiplexer outputting the input data to the write address;
a register storing the input data to the write address;
a state detector monitoring an underflow condition of the register based on a read address and a converted write address;
a second counter counting clock signal pulses of the predetermined operation frequency to create the read address when an output of the state detector does not indicate an underflow condition, and maintaining a previous address when the output of the state detector indicates an underflow condition; and
a multiplexer outputting the input data corresponding to the read address from among the data of the register.

16. The synchronizer of claim 9, wherein each of the flow control buffers comprises:
a first counter counting clock signal pulses of the predetermined operation frequency to create a write address;
a demultiplexer outputting channel output data to the write address;
a register storing the channel output data to the write address;
a state detector watching the underflow and overflow conditions of the register based on a read address and the write address;
a second counter counting the clock signal pulses of the predetermined operation frequency to create the read address when an output of the state detector does not indicate an underflow condition, and maintaining a previous address when the output of the state detector indicates an underflow condition; and
a multiplexer outputting the channel output data corresponding to the read address from among the data of the register.

17. The synchronizer of claim 16, wherein the output selector outputs the input data written in the memory to the flow control buffer which is not in an overflow condition, when the output of the state detector does not indicate an overflow condition, and a channel area of the memory is not in an underflow condition.

18. A method of synchronizing multi-rate input data, comprising:
receiving the multi-rate input data from at least two channels;
converting the multi-rate input data into a single predetermined operation frequency;
writing converted channel data corresponding to the multi-rate input data to a single memory; and
outputting the converted channel data written to the memory at the predetermined operation frequency based on bus arbitration.

19. The method of claim 18, wherein the memory is a single port static random access memory.

20. The method of claim 18, wherein the memory is a first-in-first-out type.

21. The method of claim 18, wherein the converted channel data is transferred to the single memory when a register used in the conversion is not in an underflow condition.

22. The method of claim 21, wherein the register is a first-in-first-out type, and the underflow condition corresponds to an address difference between a last write address which is written in an internal register and a last read address which is read from the internal register that is less than a predetermined value.

23. The method of claim 18, further comprising outputting the converted channel data to the single memory by allocating time sections with respect to the converted channel data in proportion to data rates of the corresponding input data.

24. The method of claim 23, wherein an input selector outputs the converted channel data to the memory with a top priority once for each of allocated time sections.

25. The method of claim 18, wherein the outputting comprises:
selecting data of the at least two channels written in the memory based on overflow and underflow conditions on an output path;
storing, temporarily, channel outputs from the memory in respective buffers based on the bus arbitration or selected data of the at least two channels; and
outputting the channel outputs to a bus at the predetermined operation frequency.

26. The method of claim 25, wherein the channel outputs of the memory are output to the respective buffers which are not in an overflow condition, when any one of the respective buffers is not in an overflow condition, and a corresponding channel area of the memory is not in an underflow condition.

27. The method of claim 25, wherein the respective buffers output the corresponding channel outputs to the bus, when the bus is requested while an internal register of the respective buffers is not in an underflow condition, and a bus occupation is granted in response to the bus request.

28. The method of claim 27, wherein the internal register is a first-in-first-out type, and the underflow and overflow conditions of the internal register are determined by an address difference between a last write address which is written in the internal register and a last read address which is read from the internal register.

29. The method of claim 27, wherein when the bus occupation is granted with respect to any flow control buffer, and a corresponding channel area of the memory is in an underflow condition, the converted channel data written in the memory is stored in a different flow control buffer based on a control of an output selector, so that the different flow control buffer may immediately occupy the bus when the different flow control buffer attains a bus grant.

30. The method of claim 27, wherein one of the buffers does not attain a bus grant, the converted channel data written in the memory is written in a different buffer, and a different flow control buffer may immediately occupy the bus when the different flow control buffer attains a bus grant.
